(19) United States
(12) Patent Application Publication
(10) Pub. No.: US 2025/0215277 A1
(43) Pub. Date: Jul. 3, 2025

(54) ADHESIVE SHEET AND RELEASE METHOD

(71) Applicant: LINTEC Corporation, Tokyo (JP)

(72) Inventors: Kenta NISHIJIMA, Tokyo (JP); Go ONISHI, Tokyo (JP); Haruki SUEYOSHI, Tokyo (JP); Tomofumi KATO, Tokyo (JP); Takashi SUGINO, Tokyo (JP); Mutsumi MASUMOTO, Beppu-shi (JP)

(21) Appl. No.: 19/085,349

(22) Filed: Mar. 20, 2025

Related U.S. Application Data
(63) Continuation of application No. PCT/JP2023/034250, filed on Sep. 21, 2023.

(30) Foreign Application Priority Data
Sep. 22, 2022 (JP) 2022-151756
Sep. 22, 2022 (JP) 2022-151757
Mar. 31, 2023 (JP) 2023-058459
Mar. 31, 2023 (JP) 2023-058460
Mar. 31, 2023 (JP) 2023-058462
Mar. 31, 2023 (JP) 2023-058463

(51) Int. Cl. C09J 7/38; C09J 151/00

(52) U.S. Cl. CPC C09J 7/38; C09J 151/003; C09J 2301/204; C09J 2301/302; C09J 2301/308; C09J 2301/408; C09J 2451/00

(57) ABSTRACT

A pressure sensitive adhesive sheet includes a base material and a pressure sensitive adhesion layer having unevenness on the layer surface. The pressure sensitive adhesion layer includes an underlying base constituted by a part from a concave portion where, in the thickness direction of the pressure sensitive adhesion layer, a thickness of the pressure sensitive adhesion layer is smallest, to a face on the opposite side of the surface with the unevenness, and a convex portion provided on the underlying base. The pressure sensitive adhesion layer satisfies Relational Expression (1) given below.

$$0.25 < S / H < 4.75 \qquad Relational Expression ( 1 )$$

(In Relational Expression (1), S represents a thickness of the underlying base, and H represents a height of the convex portion.)

### CROSS-REFERENCE TO RELATED APPLICATIONS

This application is a Continuation of International Patent Application No. PCT/JP2023/034250, filed Sep. 21, 2023, which claims the benefit of Japanese Patent Application No. 2022-151756, filed on Sep. 22, 2022; the Japanese Patent Application No. 2022-151757, filed on Sep. 22, 2022; the Japanese Patent Application No. 2023-058459, filed on Mar. 31, 2023; the Japanese Patent Application No. 2023-058460, filed on Mar. 31, 2023; the Japanese Patent Application No. 2023-058462, filed on Mar. 31, 2023; and the Japanese Patent Application No. 2023-058463, filed on Mar. 31, 2023, all of which are hereby incorporated by reference herein in their entirety.

### BACKGROUND

### Field

The present disclosure relates to a pressure sensitive adhesive sheet and a release method.

### Description of the Related Art

The pressure sensitive adhesive sheet can be used for temporarily holding an object. For example, such a pressure sensitive adhesive sheet can be used for transferring an object to a desired position.

A pressure sensitive adhesive sheet has various shapes in accordance with its application. For example, Japanese Patent Laid-Open No. 2021-147418 A describes that a groove is provided on a surface of a pressure sensitive adhesive layer in such a manner that air bubbles can be removed after bonding.

### SUMMARY

According to an embodiment of the present invention, a pressure sensitive adhesive sheet, including a base material and a pressure sensitive adhesion layer having unevenness on a surface of the layer, the pressure sensitive adhesive sheet being characterized in that the pressure sensitive adhesion layer includes: an underlying base constituted by a part from a concave portion where, in a thickness direction of the pressure sensitive adhesion layer, a thickness of the pressure sensitive adhesion layer is smallest, to a face on an opposite side of the surface with unevenness; and a convex portion provided on the underlying base, and the pressure sensitive adhesion layer satisfies Relational Expression (1) given below:

$$0.25 < S / H < 4.75 \qquad Relational Expression ( 1 )$$

where in Relational Expression (1), S represents a thickness of the underlying base, and H represents a height of the convex portion.

Further features of the present invention will become apparent from the following description of exemplary embodiments with reference to the attached drawings.

### BRIEF DESCRIPTION OF THE DRAWINGS

FIG. 1 is a cross-sectional view of a sheet according to an embodiment.

FIG. 2A is a cross-sectional view illustrating an example of unevenness provided in a sheet.

FIG. 2B is a cross-sectional view illustrating an example of unevenness provided in a sheet.

FIG. 3A is a top view illustrating an example of unevenness provided in a sheet.

FIG. 3B is a top view illustrating an example of unevenness provided in a sheet.

FIG. 3C is a top view illustrating an example of unevenness provided in a sheet.

FIG. 4A is a cross-sectional view illustrating an example of unevenness provided in a sheet.

FIG. 4B is a cross-sectional view illustrating an example of unevenness provided in a sheet.

FIG. 4C is a cross-sectional view illustrating an example of unevenness provided in a sheet.

FIG. 5A is a diagram for explaining a method of expanding a sheet.

FIG. 5B is a diagram for explaining a method of expanding a sheet.

FIG. 6 is a flowchart of an element release method and an element transfer method according to one embodiment.

### DESCRIPTION OF THE EMBODIMENTS

Embodiments will be described in detail below with reference to the accompanying drawings. It should be noted that the following embodiments are not intended to be limited to the invention according to the appended claims, and not all of the combinations of features described in the embodiments are essential to the invention. Two or more features among a plurality of the features described in the embodiments may be optionally combined. The same or similar components are denoted by the same reference signs, and redundant description thereof is omitted.

An object temporarily held by a pressure sensitive adhesive sheet is released (picked up) from the pressure sensitive adhesive sheet in a subsequent step. In particular, in the case of holding an object that is weak against external force, such as a semiconductor element, it is desirable that the holding power by the sheet for the object is not excessively high in order to prevent breakage of the object at the time of release.

As a result of intensive studies, the present inventors have found that by providing unevenness on a surface of a pressure sensitive adhesion layer included in a pressure sensitive adhesive sheet, a pickup force required for picking up an object from the pressure sensitive adhesive sheet is lowered, whereby the above-described issue can be solved. The present inventors have further conducted various studies and have completed the present invention.

An object held on a pressure sensitive adhesive sheet can be picked up with a milder operation.

### Definitions

In the present specification, mass-average molecular weight (Mw) and number-average molecular weight (Mn) are standard polystyrene conversion values measured by a size exclusion chromatography method, and specifically are values measured in accordance with JIS K7252-1:2016. In the present specification, “(meth)acrylic acid” refers to both “acrylic acid” and “methacrylic acid”, and the same shall apply to other similar terms.

In the present specification, when one or more lower limit values and one or more upper limit values of a numerical range (for example, a range of a content and the like) are described, it can be understood that a combination of any lower limit value and any upper limit value is described. For example, the description “being preferably 1 or more, more preferably 2 or more, and even more preferably 3 or more, and being preferably 9 or less, more preferably 8 or less, and even more preferably 7 or less” clearly means that the numerical range may be any of 1 or more and 9 or less, 1 or more and 8 or less, 1 or more and 7 or less, 2 or more and 9 or less, 2 or more and 8 or less, 2 or more and 7 or less, 3 or more and 9 or less, 3 or more and 8 or less, and 3 or more and 7 or less.

### Configuration of Sheet

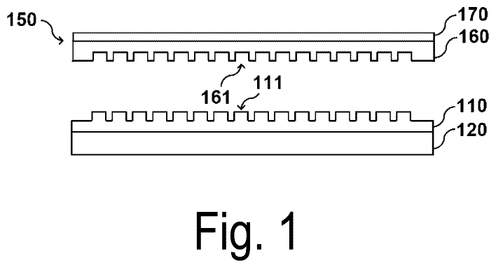

A pressure sensitive adhesive sheet according to one embodiment of the present invention includes a base material 120 and a pressure sensitive adhesion layer 110 having unevenness on a surface of the layer. The pressure sensitive adhesive sheet is used for temporarily holding an element and transferring it to a transfer destination. For example, the pressure sensitive adhesive sheet can be used for receiving an element held by another holding substrate, temporarily holding the element, and transferring the element to a desired position of a transfer destination. The base material 120 may support the pressure sensitive adhesion layer 110. Hereinafter, the configuration of such sheet will be described with reference to FIG. 1 illustrating a schematic diagram of the sheet according to one embodiment. In the present specification, the pressure sensitive adhesive sheet may be simply referred to as a sheet.

### Base Material

The base material 120 functions as a support configured to support the pressure sensitive adhesion layer 110. The base material 120 is located at a surface of the pressure sensitive adhesion layer 110 on the opposite side of the surface having the unevenness.

As will be described later, the sheet according to the present embodiment can be expanded. From this point of view, a flexible base material may be used as the base material 120. By using a flexible base material as the base material 120, it is possible to improve a cushioning property when holding an element, to laminate the sheet with ease, or to form the sheet in a roll shape. As the base material 120, for example, a resin film can be used. The resin film is a film using a resin-based material as a main material, may be made of a resin material, and may contain an additive in addition to the resin material. The resin film may have laser beam permeability.

Specific examples of the resin film include: a polyolefin-based film such as a polyethylene film such as a low density polyethylene (LDPE) film, a linear-chain low density polyethylene (LLDPE) film and a high density polyethylene (HDPE) film, a polypropylene film, a polybutene film, a polybutadiene film, a poly(4-methyl-1-pentene) film, an ethylene-norbornene copolymer file, and a norbornene resin film; an ethylene-based copolymer-based film such as an ethylene-vinyl acetate copolymer film, an ethylene-(meth)acrylic acid copolymer film, and an ethylene-(meth)acrylic acid ester copolymer film; a polyvinyl chloride-based film such as a polyvinyl chloride film and a vinyl chloride copolymer film; a polyester-based film such as a polyethylene terephthalate film and a polybutylene terephthalate film; a polyurethane film; a polyimide film; a polystyrene film; a polycarbonate film; and a fluorine resin film. In addition, a film containing a mixture of two or more types of materials, a crosslinking film in which resin forming these films is cross-linked, and a modified film such as an ionomer film may be used. The base material 120 may be a laminated film in which two or more types of resin films are laminated.

From the viewpoint of facilitating expansion of the sheet, the base material 120 is preferably a polyolefin-based film or a vinyl chloride copolymer film. Examples of the polyolefin-based film include a polyethylene film, a polypropylene film, and a copolymer containing an unsubstituted olefin such as ethylene or propylene as a constitutional unit, such as an ethylene-based copolymer containing an ethylene-methacrylic acid copolymer (EMAA). Examples of the vinyl chloride copolymer film include a vinyl chloride-vinylidene chloride copolymer film, a vinyl chloride-vinyl acetate copolymer film, and a vinyl chloride-ethylene copolymer film. The form of the copolymer described above is not particularly limited. The copolymer may be any of a block copolymer, a random copolymer, an alternating copolymer, and a graft copolymer. These films may contain other resin components or additives.

The thickness of the base material 120 is not particularly limited. However, in order to achieve both a support function and a roll-form winding function, the thickness thereof is preferably 10 μm or more, more preferably 25 μm or more, even more preferably 40 μm or more; on the other hand, it is preferably 500 μm or less, more preferably 200 μm or less, even more preferably 150 μm or less, still even more preferably 150 μm or less, still even more preferably 120 μm or less, and particularly preferably 90 μm or less.

In order to facilitate uniform expansion of the sheet, the Young's modulus of the base material 120 is preferably 50 MPa or more, more preferably 80 MPa or more, and even more preferably 120 MPa or more; and is preferably 2500 MPa or less, more preferably 1000 MPa or less, and even more preferably 500 MPa or less. In the present specification, the Young's modulus is measured in accordance with JIS K7161-1:2014.

Similarly, in order to facilitate the expansion of the sheet, the elongation at break of the base material 120 is preferably 105% or more, more preferably 150% or more, and even more preferably 250% or more. In the present specification, the elongation at break is measured in accordance with JIS K 7127:1999.

### Pressure Sensitive Adhesion Layer

The pressure sensitive adhesion layer 110 is a layer having a pressure sensitive adhesive property, and may contain resin. As described above, the pressure sensitive adhesion layer 110 has unevenness on its surface. The sheet may include two or more pressure sensitive adhesion layers 110. For example, the sheet may include a laminating body formed of one, or two or more types of pressure sensitive adhesion layers 110.

Composition of Pressure Sensitive Adhesion Layer Examples of the resin contained in the pressure sensitive adhesion layer 110 include a rubber-based resin such as a polyisobutylene-based resin, a polybutadiene-based resin and a styrene-butadiene based resin, an acrylic resin, a urethane-based resin, a polyester-based resin, an olefin-based resin, a silicone-based resin, and a polyvinyl ether-based resin. The pressure sensitive adhesion layer may have heat resistance, and examples of the material of the pressure sensitive adhesion layer 110 having such heat resistance include a polyimide-based resin and a silicone-based resin. The pressure sensitive adhesion layer 110 may contain a copolymer having two or more types of constitutional units. The form of the copolymer described above is not particularly limited. The copolymer may be any of a block copolymer, a random copolymer, an alternating copolymer, and a graft copolymer.

The resin contained in the pressure sensitive adhesion layer 110 is preferably a pressure sensitive adhesive resin having a pressure sensitive adhesive property alone. The resin is preferably a polymer having a mass-average molecular weight (Mw) of 10000 or more. From the viewpoint of improving the holding performance, the mass-average molecular weight (Mw) of the resin is preferably 10000 or more, more preferably 70000 or more, and even more preferably 140000 or more. From the viewpoint of suppressing the storage modulus to a level equal to or lower than a predetermined value, Mw is preferably 2 million or less, and more preferably 1200 thousand or less. From the viewpoint of improving the holding performance, the number-average molecular weight (Mn) of the resin is preferably 10000 or more, more preferably 50000 or more, and even more preferably 100000 or more. Furthermore, from the viewpoint of suppressing the storage modulus to a level equal to or lower than a predetermined value, it is preferably 2 million or less, more preferably 1500 thousand or less, and even more preferably 1200 thousand or less. As will be described later, when the pressure sensitive adhesion layer 110 contains resin derived from an energy-reactive resin, the mass-average molecular weight (Mw) and the number-average molecular weight (Mn) refer to the mass-average molecular weight (Mw) and the number-average molecular weight (Mn) before a crosslinking reaction by energy application. The glass transition temperature (Tg) of the resin is preferably −75° C. or higher, and more preferably −70° C. or higher; and is preferably 5° C. or lower, and more preferably −20° C. or lower. When Tg falls within the above-described range, the holding performance and the storage modulus of the obtained pressure sensitive adhesion layer 110 are likely to fall within ranges to be described later.

The amount of the resin contained in the pressure sensitive adhesion layer 110 with respect to the total amount of components constituting the pressure sensitive adhesion layer 110 can be appropriately set in accordance with the required holding performance and storage modulus of the pressure sensitive adhesion layer 110; it is preferably 30 mass % or more, more preferably 50 mass % or more, even more preferably 70 mass % or more, even more preferably 80 mass % or more and even more preferably 90 mass % or more, and is preferably 99.99 mass % or less, more preferably 99.95 mass % or less, even more preferably 99.90 mass % or less, even more preferably 99.80 mass % or less, and even more preferably 99.50 mass % or less.

From the viewpoint of stabilizing the shape of unevenness on the surface of the pressure sensitive adhesion layer 110, the shear storage modulus of the pressure sensitive adhesion layer is preferably 0.001 MPa or more, more preferably 0.01 MPa or more, even more preferably 0.03 MPa or more, and even more preferably 0.07 MPa or more. On the other hand, it is preferable that the shear storage modulus of the pressure sensitive adhesion layer 110 be low in terms of being able to suppress positional deviation when holding the element. From such a viewpoint, the shear storage modulus of the pressure sensitive adhesion layer 110 is preferably 100 MPa or less, more preferably 50 MPa or less, even more preferably 20 MPa or less, and particularly preferably 5 MPa or less. In the present specification, the shear storage modulus is measured in accordance with JIS K7244-1:1998. To be specific, a cylindrical sample with a thickness of 3 mm and a diameter of 8 mm is prepared, and then the shear storage modulus of the sample is measured by a torsional shear method under an environment of 1 Hz and 23° C. using a viscoelasticity measuring apparatus, whereby the shear storage modulus of the pressure sensitive adhesion layer 110 can be measured.

In one embodiment, the resin contained in a pressure sensitive adhesive composition forming the pressure sensitive adhesion layer 110 may include a thermoplastic resin. In other words, the pressure sensitive adhesion layer 110 may be formed of the thermoplastic resin. In the case of using the thermoplastic resin, unevenness can be easily formed on the pressure sensitive adhesion layer 110 by heating and softening the resin, and it is easy to maintain the formed shape of unevenness by cooling. Examples of the thermoplastic resin include a rubber-based resin, an acrylic resin, a urethane-based resin, and an olefin-based resin. As an example, a polybutadiene-based thermoplastic elastomer in which butadiene is used as a monomer, a styrene-based thermoplastic elastomer in which styrene is used as a monomer, and an acryl-based thermoplastic elastomer in which (meth)acrylic acid or (meth)acrylic acid ester is used as a monomer may be cited.

Composition examples of the pressure sensitive adhesion layer 110 will be described below. Note that the compositions of the pressure sensitive adhesion layer 110 are not limited to the ones described below.

### Acrylic Resin (A)

In one embodiment, the pressure sensitive adhesive composition forming the pressure sensitive adhesion layer 110 contains an acrylic resin. The acrylic resin is resin containing (meth)acrylic acid or (meth)acrylic acid ester as a monomer. From the viewpoint of increasing adhesive strength, the mass-average molecular weight (Mw) of the acrylic resin is preferably 10 thousand or more, more preferably 100 thousand or more, and even more preferably 500 thousand or more. Furthermore, from the viewpoint of suppressing the storage modulus to a level equal to or lower than a predetermined value, it is preferably 2 million or less, more preferably 1500 thousand or less, and even more preferably 1200 thousand or less.

The glass transition temperature (Tg) of the acrylic resin is preferably-75° C. or higher, and more preferably −70° C. or higher; and is preferably 5° C. or lower, and more preferably −20° C. or lower. When Tg falls within the above-described range, it is easy to obtain the pressure sensitive adhesion layer 110 having the above-described storage modulus.

When the acrylic resin includes two or more constitutional units, the glass transition temperature (Tg) thereof can be calculated using the Fox equation. For Tg of the monomer deriving the constitutional units used here, a value described in Polymer Data Handbook or Pressure Sensitive Adhesion Handbook can be used.

Examples of (meth)acrylic acid ester constituting the acrylic resin include: (meth)acrylic acid alkyl ester in which an alkyl group constituting alkyl ester has a chain structure of 1 to 18 carbon atoms, such as methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, tert-butyl (meth)acrylate, pentyl (meth)acrylate, hexyl (meth)acrylate, heptyl (meth)acrylate, 2-ethylhexyl (meth)acrylate, isooctyl (meth)acrylate, n-octyl (meth)acrylate, n-nonyl (meth)acrylate, isononyl (meth)acrylate, decyl (meth)acrylate, undecyl (meth)acrylate, lauryl (meth)acrylate, tridecyl (meth)acrylate, myristyl (meth)acrylate, pentadecyl (meth)acrylate, palmityl (meth)acrylate, heptadecyl (meth)acrylate, and stearyl (meth)acrylate;
(meth)acrylic acid cycloalkyl ester such as isobornyl (meth)acrylate and dicyclopentanyl (meth)acrylate;
(meth)acrylic acid aralkyl ester such as benzyl (meth)acrylate;
(meth)acrylic acid cycloalkenyl ester such as dicyclopentenyl (meth)acrylate; (meth)acrylic acid cycloalkenyl oxyalkyl ester such as dicyclopentenyl oxyethyl (meth)acrylate;
imide (meth)acrylate;
glycidyl group-containing (meth)acrylic acid ester, such as glycidyl (meth)acrylate;
hydroxyl group-containing (meth)acrylic acid ester, such as hydroxymethyl (meth)acrylate, 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, and 4-hydroxybutyl (meth)acrylate; and
substituted amino group-containing (meth)acrylic acid ester, such as N-methylaminoethyl (meth)acrylate. Here, the “substituted amino group” means a group having a structure in which one or two hydrogen atoms of an amino group are substituted with a group other than hydrogen atoms.

The acrylic resin may be resin obtained by copolymerization of one, or two or more types of monomers selected from, for example, itaconic acid, vinyl acetate, acrylonitrile, styrene, and N-methylol acrylamide in addition to (meth)acrylic acid ester or (meth)acrylic acid.

Only one type of monomer or two or more types of monomers may constitute the acrylic resin. When two or more types of monomers constitute the acrylic resin, any combination and any ratio thereof can be selected as desired.

In one embodiment, the acrylic resin contains a monomer having a hydroxyl group as a constitutional unit. The acrylic resin may have, in addition to a hydroxyl group, functional groups, such as a vinyl group, a (meth)acryloyl group, an amino group, a carboxy group and an isocyanate group, that can be bonded to other compounds. These functional groups, such as the hydroxyl group of the acrylic resin, may be bonded to other compounds via a cross-linker (C) described later or may be directly bonded to other compounds without the cross-linker (C).

The amount of the acrylic resin in the total resin amount of the pressure sensitive adhesive composition can be appropriately set in accordance with the required adhesive strength and storage modulus of the pressure sensitive adhesion layer 110; it is preferably 0 mass % or more, more preferably 10 mass % or more, even more preferably 20 mass % or more and even more preferably 50 mass % or more, and is preferably 100 mass % or less, more preferably 95 mass % or less, even more preferably 80 mass % or less, and even more preferably 60 mass % or less.

### Energy-Reactive Resin (B)

In one embodiment, the pressure sensitive adhesive composition forming the pressure sensitive adhesion layer 110 contains an energy-reactive resin (B). The energy-reactive resin (B) refers to resin whose elastic modulus is improved by applying energy. The energy-reactive resin may be resin derived from an energy-reactive monomer. In this case, the energy-reactive resin is resin obtained by polymerizing energy-reactive monomers by applying energy.

Examples of the energy-reactive resin include an energy ray-reactive resin and a heat-reactive resin. The energy ray-reactive resin refers to resin whose elastic modulus is improved by being irradiated with energy rays. For example, the energy-reactive resin may be an energy ray curable resin. The heat-reactive resin refers to resin whose elastic modulus is improved by being heated. The resin contained in the pressure sensitive adhesion layer 110 is more preferably derived from a thermoplastic energy-reactive resin, and even more preferably derived from a thermoplastic energy ray-reactive resin. The type of the energy ray is not particularly limited, and examples thereof include an ultraviolet ray, an electron beam, and ionizing radiation. The energy ray is preferably an ultraviolet ray, that is, the resin is preferably an ultraviolet ray-reactive resin.

The thermoplastic energy-reactive resin refers to an energy-reactive resin having thermoplasticity at least before the application of energy. In addition, the resin being derived from an energy-reactive resin means that the resin is obtained from an energy-reactive resin. For example, the resin derived from an energy-reactive resin is a cross-linked energy-reactive resin.

In a case of using such energy-reactive resin, by applying energy (for example, by irradiation with energy rays) after forming unevenness on the resin, it becomes easy to maintain the formed shape of unevenness.

As such energy-reactive resin, a polymer into which a polymerizable functional group is introduced can be used. The polymerizable functional group is a functional group that is cross-linked by application of energy (for example, irradiation with energy rays). Examples of the polymerizable functional group include an alkenyl group such as a vinyl group and an allyl group, a (meth)acryloyl group, an oxetanyl group, and an epoxy group.

For example, a diene-based rubber composed of a polymer having a polymerizable functional group at a main chain end and/or a side chain can be used as the energy-reactive resin. The diene-based rubber refers to a rubbery polymer having a double bond in the polymer main chain. Specific examples of the diene-based rubber include a polymer in which butadiene or isoprene is used as a monomer (that is, a polymer having a butenediyl group or a pentenediyl group as a constitutional unit). Preferable examples of the energy-reactive resin include a polybutadiene resin (PB resin), a styrene-butadiene-styrene block copolymer (SBS resin), and a styrene-isoprene-styrene block copolymer. These resins can be used as the ultraviolet ray-reactive resin.

The average value of the numbers of polymerizable functional groups per molecule in these energy-reactive resins is preferably 1.5 or more, and more preferably 2 or more, from the viewpoint of easily maintaining the shape of unevenness of the pressure sensitive adhesion layer 110. On the other hand, the above-mentioned average value is preferably 20 or less, more preferably 15 or less, and even more preferably 10 or less, from the viewpoint of enhancing the pressure sensitive adhesive property and flexibility of the pressure sensitive adhesion layer 110.

The pressure sensitive adhesion layer 110 may contain one type of resin or may contain two or more types of resin. The pressure sensitive adhesion layer 110 according to one embodiment contains a liquid resin, resin derived from an energy-reactive liquid resin, or resin derived from an energy-reactive monomer, in addition to a thermoplastic resin or resin derived from a thermoplastic energy-reactive resin. The liquid resin refers to resin in a liquid state at room temperature (25° C.) before mixing. The energy-reactive liquid resin refers to an energy-reactive resin in a liquid state at room temperature (25° C.) before mixing and before applying energy. The resin derived from the energy-reactive monomer is resin obtained by polymerizing energy-reactive monomers by applying energy. By adding the above-discussed liquid resins or monomers, it becomes easy to control the holding performance and the storage modulus of the pressure sensitive adhesion layer 110.

It is preferable that the pressure sensitive adhesion layer 110 according to one embodiment contain a resin derived from an energy-reactive liquid resin, because the shape of unevenness of the pressure sensitive adhesion layer 110 can be easily maintained. Examples of the above-discussed liquid resin include diene-based rubber, and specific examples thereof include a polybutadiene-based resin in which butadiene is used as a monomer.

The pressure sensitive adhesion layer 110 according to another embodiment includes a combination of an optional resin and resin derived from an energy-reactive liquid resin or an energy-reactive monomer. For example, the pressure sensitive adhesion layer 110 may contain an acrylic resin (A) and resin derived from an energy-reactive liquid resin or an energy-reactive monomer. With such combination as well, after forming the unevenness, by applying energy (for example, irradiation with energy rays) to the film of the mixture of the acrylic resin (A) and the energy-reactive liquid resin or the energy-reactive monomer, the energy-reactive liquid resin or the energy-reactive monomer is polymerized to make it easy to maintain the formed shape of unevenness.

Examples of the energy-reactive monomer include a bifunctional or polyfunctional compound into which a polymerizable functional group is introduced, such as an alkenyl group such as a vinyl group and an allyl group, a (meth)acryloyl group, an oxetanyl group, and an epoxy group. Preferred examples of the energy-reactive monomer include polyvalent (meth)acrylate such as bifunctional (meth)acrylate. As described above, the pressure sensitive adhesion layer 110 may include an energy ray curable resin containing polyvalent (meth)acrylate as a constitutional unit. Specific examples of the polyvalent (meth)acrylate include cycloalkyl di(meth)acrylate such as tricyclodecanedimethanol diacrylate.

The ratio of the energy-reactive resin (B) amount to the total amount of the components constituting the pressure sensitive adhesion layer 110 can be selected in accordance with the required holding performance, storage modulus, and the like of the pressure sensitive adhesion layer 110. For example, the ratio is preferably 1 mass % or more, more preferably 5 mass % or more, even more preferably 8 mass % or more and even more preferably 10 mass % or more, and is preferably 30 mass % or less, and more preferably 25 mass % or less.

In the case where the pressure sensitive adhesion layer 110 contains the acrylic resin (A) and the energy-reactive resin (B), the amount of the energy-reactive resin with respect to the acrylic resin can be selected in accordance with the required holding performance, storage modulus, and the like of the pressure sensitive adhesion layer 110. For example, the amount of the energy-reactive resin with respect to 100 parts by mass of the acrylic resin is preferably 1 part by mass or more, more preferably 5 parts by mass or more, even more preferably 8 parts by mass or more and particularly preferably 10 parts by mass or more, and is preferably 30 parts by mass or less, and more preferably 25 parts by mass or less. In this case, the energy-reactive resin is, for example, an energy ray curable resin, and is, for example, resin derived from an energy ray curable monomer. In this case, “parts by mass” is based on the mass of the solids content, and hereinafter, “parts by mass” is based on the mass of the solids content unless otherwise specified.

### Other Components of Pressure Sensitive Adhesion Layer

The pressure sensitive adhesive composition forming the pressure sensitive adhesion layer 110 may contain components other than resin. For example, the pressure sensitive adhesive composition may contain one or more of a cross-linker (C), a photopolymerization initiator (D), and other additives.

Examples of the cross-linker (C) include an isocyanate-based cross-linker, an epoxy-based cross-linker, an aziridine-based cross-linker, and a metal chelate-based cross-linker. One of these cross-linkers may be used alone, or two or more of them may be used in combination.

Among these cross-linkers, the isocyanate-based cross-linker is preferred from the viewpoint of increasing cohesive strength to enhance adhesive strength, from the viewpoint of ease of availability, and the like. Examples of the isocyanate-based cross-linker include polyvalent isocyanate compounds such as: aromatic polyisocyanate such as tolylene diisocyanate, diphenylmethane diisocyanate, and xylylene diisocyanate;
alicyclic polyisocyanate such as dicyclohexylmethane-4,4′-diisocyanate, bicycloheptane triisocyanate, cyclopentylene diisocyanate, cyclohexylene diisocyanate, methylcyclohexylene diisocyanate, methylenebis (cyclohexylisocyanate), 3-isocyanatemethyl-3,5,5-trimethylcyclohexylisocyanate, and hydrogenated xylylene diisocyanate; and
acyclic aliphatic polyisocyanate such as hexamethylenediisocyanate, trimethylhexamethylenediisocyanate, and lysinediisocyanate. Examples of the isocyanate-based cross-linker also include a trimethylol propane adduct-type modified product of the polyvalent isocyanate compound, a burette-type modified product having reacted with water, and an isocyanurate-type modified product including an isocyanurate ring.

The pressure sensitive adhesive composition may contain one type of cross-linker, or may contain two or more types of cross-linkers. The content of the cross-linker in the pressure sensitive adhesive composition is preferably 0.01 mass % or more, more preferably 0.1 mass % or more, even more preferably 0.5 mass % or more and particularly preferably 0.8 mass % or more, and is preferably 5 mass % or less, more preferably 4 mass % or less, and even more preferably 2 mass % or less, from the viewpoint of appropriately performing a crosslinking reaction.

For example, the cross-linker may be a cross-linker of the acrylic resin (A). For example, an isocyanate-based cross-linker of an isocyanurate-type modified product can be used as a cross-linker of an acrylic resin containing a monomer having a hydroxyl group as a constitutional unit. In this case, the amount of the cross-linker with respect to the acrylic resin may be selected so as to appropriately perform the crosslinking reaction. For example, the amount of the cross-linker with respect to 100 parts by mass of the acrylic resin is preferably 0.01 parts by mass or more, more preferably 0.1 parts by mass or more, even more preferably 0.5 parts by mass or more and particularly preferably 1.0 part by mass or more, and is preferably 5 parts by mass % or less, more preferably 4 parts by mass or less, and even more preferably 2 parts by mass or less.

The photopolymerization initiator (D) initiates a crosslinking reaction in response to application of energy (for example, irradiation with energy rays). When the pressure sensitive adhesive composition contains the energy-reactive resin (B), in the case where the pressure sensitive adhesion layer 110 further contains the photopolymerization initiator (D), the crosslinking reaction proceeds even by application of an energy with a relatively low energy.

Examples of the photopolymerization initiator (D) include 1-hydroxycyclohexyl phenyl ketone, benzoin, benzoin methyl ether, benzoin ethyl ether, benzoin propyl ether, benzyl phenyl sulfide, tetramethylthiuram mono-sulfide, azobisisobutyronitrile, dibenzyl, diacetyl, 8-chloroanthraquinone, 2,4,6-trimethylbenzoyl diphenyl phosphine oxide, and bis (2, 4, 6-trimethylbenzoyl)phenylphosphine oxide.

The pressure sensitive adhesive composition may contain one type of polymerization initiator or may contain two or more types of polymerization initiators. The content of the photopolymerization initiator in the pressure sensitive adhesive composition is preferably 0.01 mass % or more, and more preferably 0.1 mass % or more, and is preferably 10 mass % or less, more preferably 5 mass % or less, and even more preferably 2 mass % or less.

Examples of other additives that may be contained in the pressure sensitive adhesion layer 110 include, but are not limited to, an ultraviolet ray absorber such as a benzotriazole-based compound, an oxazolic acid amide compound, or a benzophenone-based compound; a hindered amine-based, benzophenone-based, or benzotriazole-based light stabilizer; a resin stabilizer such as an imidazole-based resin stabilizer, dithiocarbamate-based resin stabilizer, phosphorus-based resin stabilizer, or sulfur ester-based resin stabilizer; and an antioxidant, filler, pigment, extender and softner, such as a phenol-based compound such as a hindered phenol-based compound, aromatic amine-based compound, sulfur-based compound, or phosphorus-based compound such as a phosphate ester-based compound.

When the pressure sensitive adhesion layer 110 contains these additives, the content of the additives in the pressure sensitive adhesion layer 110 is preferably 0.0001 mass % or more, more preferably 0.01 mass % or more, particularly preferably 0.1 mass % or more and even more preferably 1 mass % or more, and is preferably 20 mass % or less, more preferably 10 mass % or less, and even more preferably 5 mass % or less.

### Shape of Pressure Sensitive Adhesion Layer

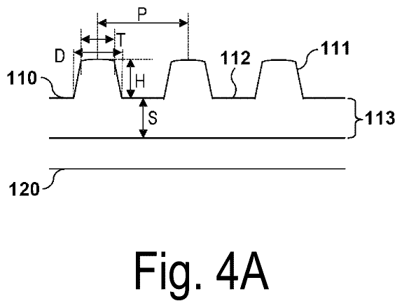

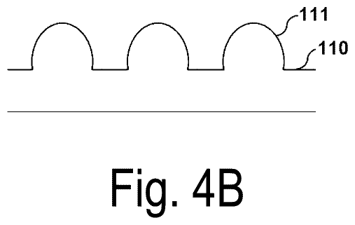

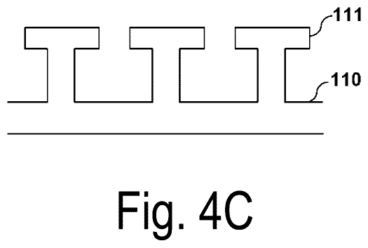

The surface of the pressure sensitive adhesion layer 110 according to the present embodiment has unevenness. More specifically, the pressure sensitive adhesion layer 110 includes an underlying base 113 and a convex portion 111 provided on the underlying base 113. FIG. 4A illustrates a cross-sectional view of the pressure sensitive adhesion layer 110 according to one embodiment; the cross-sectional view passes through the convex portions 111 and is perpendicular to the surface of the pressure sensitive adhesion layer 110. As illustrated in FIG. 4A, the convex portion 111 and the underlying base 113 may be integrated with each other. That is, the convex portion 111 and the underlying base 113 may be formed of the same material. The convex portion 111 and the underlying base 113 can be integrally formed.

As illustrated in FIG. 4A, the pressure sensitive adhesion layer 110 can include the convex portion 111 and a concave portion 112. The concave portion 112 is a portion where the thickness of the pressure sensitive adhesion layer 110 is smallest, and is, for example, a portion where the thickness of the pressure sensitive adhesion layer 110 takes a minimum value. In this case, the underlying base 113 can be defined as a part extending from the concave portion 112 to a face (a contact surface with the base material 120 in the example of FIG. 4A) on the opposite side of the surface having unevenness in the thickness direction of the pressure sensitive adhesion layer 110. As illustrated in FIG. 4A, the pressure sensitive adhesion layer 110 can include, on its surface, a plurality of the convex portions 111 separated from each other with a boundary defined by the underlying base 113. Each of the plurality of convex portions 111 may be separated from each other by the underlying base 113 continuously provided over the entire pressure sensitive adhesion layer 110.

In the present embodiment, the thickness(S) of the underlying base 113 and the height (H) of the convex portion 111 satisfy the following Relational Expression (1).

$$0.25 < S / H < 4.75 \qquad Relational Expression ( 1 )$$

According to the study by the inventors of the present application, a pickup force required for picking up an object from the pressure sensitive adhesive sheet can be reduced by forming unevenness on the pressure sensitive adhesion layer 110. In particular, the pickup force required for picking up the object from the pressure sensitive adhesive sheet can be further reduced by forming unevenness on the pressure sensitive adhesion layer 110 in such a manner as to satisfy Relational Expression (1). As a reason for this, the inventors of the present application assume that the concave portion 112 also contributes to the holding of the object for the deformation of the surface of the pressure sensitive adhesion layer 110, and when the height (H) of the convex portion 111 is relatively large, the object is likely to be released from the concave portion 112. In addition, as a reason for this, the inventors of the present application assume that when the thickness(S) of the underlying base 113 is relatively small, the surface of the pressure sensitive adhesion layer 110 is unlikely to be deformed, and thus the object is likely to be released from the concave portion 112.

As discussed above, from the viewpoint of reducing the pickup force required for picking up the object from the pressure sensitive adhesive sheet, the value of S/H is less than 4.75, preferably less than 4.25, more preferably less than 3.50, even more preferably less than 3.00, even more preferably less than 2.50, even more preferably less than 2.00, and even more preferably less than 1.75. On the other hand, from the viewpoint of raising the holding power, the value of S/H exceeds 0.25, preferably exceeds 0.50, more preferably exceeds 0.75, and even more preferably exceeds 1.00.

In one embodiment, the height (H) of the convex portion 111 is preferably 1 μm or more, more preferably 2 μm or more, and even more preferably 3 μm or more, from the viewpoint of reducing the pickup force. On the other hand, from the viewpoint of improving stability of the shape, the height (H) of the convex portion 111 is preferably 20 μm or less, more preferably 15 μm or less, and even more preferably 10 μm or less.

From the viewpoint of reducing the pickup force, the thickness(S) of the underlying base 113 is preferably 50 μm or less, more preferably 40 μm or less, even more preferably 30 μm or less, and even more preferably 20 μm or less. The thickness(S) of the underlying base 113 is preferably 1 μm or more, more preferably 3 μm or more, and even more preferably 5 μm or more, from the viewpoint of raising the holding power.

In one embodiment, the underlying base 113 has a uniform thickness. For example, the thickness of the pressure sensitive adhesion layer 110 may be uniform in each of a plurality of the concave portions 112 included in the pressure sensitive adhesion layer 110. In one embodiment, the heights of the plurality of convex portions 111 included in the pressure sensitive adhesion layer 110 are uniform. On the other hand, the thickness of the underlying base 113 does not need to be uniform, and the heights of the convex portions 111 do not need to be uniform. In such a case, in at least part of the pressure sensitive adhesion layer 110, at least half of the pressure sensitive adhesion layer 110, or the entire pressure sensitive adhesion layer 110, the height (H) of the convex portion 111, the thickness(S) of the underlying base 113, or the value of S/H falls within the range described above.

As an example, the pressure sensitive adhesion layer 110 may include a first plurality of convex portions having a first uniform height and a second plurality of convex portions having different heights. In this case, the second plurality of convex portions may have a second uniform height. For example, the convex portions 111 may be constituted of the first convex portions and the second convex portions as discussed above. As another example, the pressure sensitive adhesion layer 110 may include the plurality of convex portions 111 having random heights.

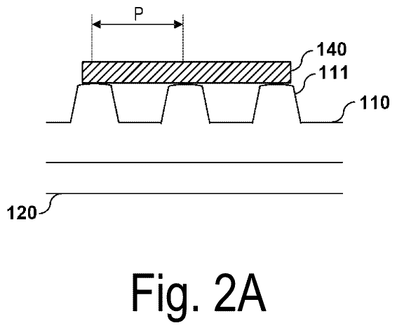

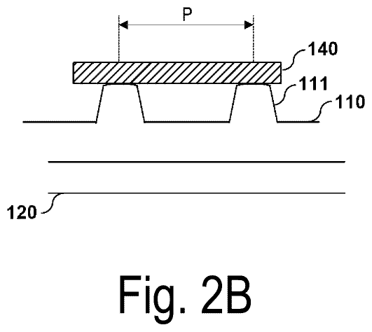

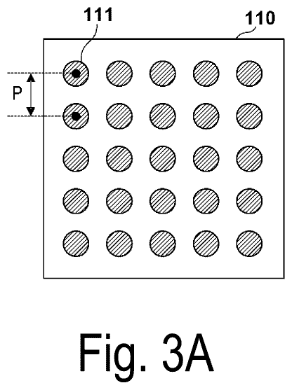

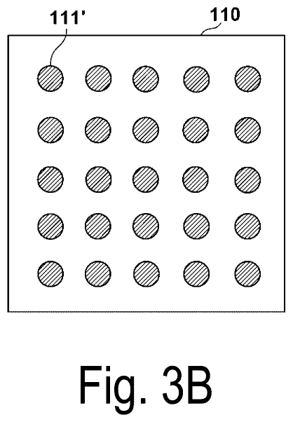

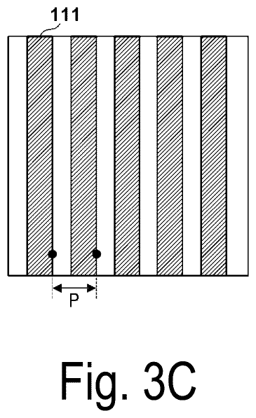

FIGS. 2A to 2C are side views illustrating the shape of the pressure sensitive adhesion layer 110, while FIGS. 3A to 3C are top views illustrating the shape of the pressure sensitive adhesion layer 110. FIGS. 2A and 3A illustrate an example of the pressure sensitive adhesion layer 110 before being expanded, while FIGS. 2B and 3B illustrate an example of the pressure sensitive adhesion layer 110 after being expanded. While an element 140 held on the convex portions 111 of the pressure sensitive adhesion layer 110 is depicted in FIGS. 2A to 2C, the element 140 held on the convex portions 111 is omitted in FIGS. 3A to 3C.

As illustrated in FIGS. 2A and 3A, the convex portions 111 may be regularly arranged on the surface of the pressure sensitive adhesion layer 110. The regular arrangement of the convex portions means that the convex portions are arranged on a straight line at constant intervals. On the other hand, the convex portions 111 may be arranged in such a manner that the intervals regularly vary. For example, the interval between the convex portions may be short in the central portion of the sheet while the interval between the convex portions may be long in the peripheral portion of the sheet. Further, the convex portions may be arranged irregularly.

FIG. 3C is a top view illustrating another shape of the pressure sensitive adhesion layer 110. As illustrated in FIG. 3C, the stripe-shaped convex portions 111 may be provided on the surface of the pressure sensitive adhesion layer 110. In FIG. 3C, the line-shaped convex portions 111 having a constant width are arranged side by side at constant intervals. The width or interval of the line-shaped convex portions 111 may vary regularly, or the line-shaped convex portions 111 may be arranged irregularly.

The sheet according to the present embodiment can be expanded. For example, the pressure sensitive adhesion layer 110 illustrated in FIGS. 2A and 3A is transformed, due to the expansion, into a pressure sensitive adhesion layer 110′ illustrated in FIGS. 2B and 3B. When the pressure sensitive adhesion layer 110 and the pressure sensitive adhesion layer 110′ are compared, in the pressure sensitive adhesion layer 110′, a pitch P for the convex portions 111 is widened by the expansion, and the number of convex portions 111 holding one element 140 is decreased. With this, in the pressure sensitive adhesion layer 110′, the power for holding the element 140 by the convex portions 111 is reduced as compared with the pressure sensitive adhesion layer 110.

The pitch P of the convex portions 111 before expansion is preferably 1 μm or more, more preferably 5 μm or more, even more preferably 10 μm or more, and even more preferably 15 μm or more, from the viewpoint of adjusting the holding power. On the other hand, the pitch P is preferably 100 μm or less, more preferably 75 μm or less, even more preferably 50 μm or less, even more preferably 35 μm or less, and even more preferably 25 μm or less, from the viewpoint of increasing a contact area between the pressure sensitive adhesion layer 110 and the element to enhance the holding power. Here, the pitch P of the convex portions 111 refers to a distance between a center point of one convex portion 111 optionally selected and a center point of another convex portion 111 closest to the one convex portion 111. For example, in the case of FIG. 2A, the pitch P of the convex portions 111 represents a distance between the center point of one convex portion 111 on a straight line on which the convex portions 111 are arranged at constant intervals and the center point of another convex portion 111 closest to the one convex portion 111. When the convex portions 111 are arranged on a plurality of straight lines, the pitch P represents a distance between the center points of the convex portions on the straight line on which the convex portions 111 are arranged at the shortest pitch. In the present specification, the interval between the convex portions 111 refers to an interval between the centers of the convex portions.

A specific shape of the convex portion 111 is not particularly limited. For example, the convex portion 111 may have a pillar shape. As a specific example, the convex portion 111 may have a cylindrical shape or a prismatic shape. In addition, the convex portion 111 may extend in a line shape as described above, or may extend in a curved shape such as a wave shape. The convex portions 111 may be tapered.

FIG. 4A illustrates a cross-sectional view of the pressure sensitive adhesion layer 110 according to one embodiment; the cross-sectional view passes through the convex portions 111 and is perpendicular to the surface of the pressure sensitive adhesion layer 110. The convex portion 111 illustrated in FIG. 4A is tapered, that is, the convex portion 111 is tapered toward the tip. As illustrated in FIG. 4B, the tip of the convex portion 111 may have a curved face. With this configuration, since an impact when an element is held on the pressure sensitive adhesion layer 110 is further alleviated, it is easy for the pressure sensitive adhesion layer 110 to hold the element without causing the element to be displaced. On the other hand, the tip of the convex portion may take a plane shape.

As another example, the convex portion may be hemispherical or part of a sphere, as illustrated in FIG. 4B. As illustrated in FIG. 4C, the convex portion 111 may have a T shape. As still another example, the convex portion 111 may have a shape in which a plurality of particles are gathered, a mushroom shape, a lotus leaf surface shape, or a needle shape. As still another example, the surface of the pressure sensitive adhesion layer 110 may take a rough or fibrous surface, and such a surface can also be considered as having unevenness.

The width or diameter of each convex portion 111 is preferably 1 μm or more, more preferably 2 μm or more, even more preferably 5 μm or more, and even more preferably 10 μm or more, from the viewpoint of maintaining the holding power for the element. On the other hand, from the viewpoint of improving easiness of releasing the element, the width or diameter is preferably 100 μm or less, more preferably 50 μm or less, even more preferably 30 μm or less, and even more preferably 20 μm or less. In this case, the width and the diameter of the convex portion 111 respectively refer to a minimum distance and a maximum distance (indicated by “D” in FIG. 4A) between two parallel lines in contact with both sides of the convex portion 111 on the surface of the underlying base 113.

The area of each convex portion 111 is preferably 10 μm² or more, more preferably 20 μm² or more, and even more preferably 30 μm² or more, from the viewpoint of maintaining the holding power for the element. On the other hand, from the viewpoint of improving easiness of releasing the element, the area is preferably 2000 μm² or less, more preferably 1000 μm² or less, and even more preferably 500 μm² or less. In this case, the area of the convex portion 111 refers to an area of a portion protruding from the surface of the underlying base 113 (an area of a circle having the diameter D in the case of FIG. 4A).

In addition, the total area of the convex portions 111 with respect to the area of the pressure sensitive adhesion layer 110 is preferably 1% or more, more preferably 5% or more, even more preferably 10% or more, even more preferably 18% or more, and even more preferably 40% or more, from the viewpoint of maintaining the holding power for the element. On the other hand, the total area of the convex portions with respect to the area of the pressure sensitive adhesion layer 110 is preferably 95% or less, more preferably 75% or less, and even more preferably 60% or less, from the viewpoint of improving easiness of releasing the element.

The unevenness of the pressure sensitive adhesion layer 110 may be designed in accordance with the shape of the element to be held on the sheet. For example, the ratio of an adhesion area of the pressure sensitive adhesion layer 110 and one element to the area of one element is preferably 1% or more, more preferably 2% or more, even more preferably 3% or more, even more preferably 4% or more, even more preferably 5% or more, even more preferably 7% or more, and even more preferably 10% or more, with respect to 100% of the area of one element, from the viewpoint of maintaining the holding power for the element. On the other hand, the ratio of the adhesion area of the pressure sensitive adhesion layer 110 and one element to the area of one element is preferably 95% or less, more preferably 70% or less, even more preferably 50% or less, and even more preferably 30% or less, from the viewpoint of improving easiness of releasing the element. In the case of FIG. 4A, the adhesion area corresponds to an area of a circle with a diameter T. When the holding position of the element on the sheet is deviated, the adhesion area may change. In this case, it is preferable for the ratio of the adhesion area to fall within the above-described range regardless of the position of the object to be treated.

### Release Sheet

As illustrated in FIG. 1, the pressure sensitive adhesive sheet according to the present embodiment may include a release sheet 150, which is in contact with the pressure sensitive adhesion layer 110 and has an uneven surface complementary to the uneven surface of the pressure sensitive adhesion layer 110. FIG. 1 depicts a state in which the pressure sensitive adhesion layer 110 and the release sheet 150 are separated from each other for the sake of explanation.

The release sheet 150 includes a release layer 160. The release layer 160 can be easily released from the pressure sensitive adhesion layer 110. The release layer 160 may have an uneven surface complementary to the uneven surface of the pressure sensitive adhesion layer 110. That is, the release layer 160 includes a concave portion 161, and the concave portion 161 has a shape complementary to the convex portion 111. However, it is not essential for the concave portion 161 to have a shape complementary to the convex portion 111.

The release sheet 150 may include a base material 170 on a surface that is not in contact with the pressure sensitive adhesion layer 110. The base material 170 can be designed similarly to the base material 120, but need not have the same composition or structure as the base material 120. For example, the material of the base material 120 may be EMAA while the material of the base material 170 may be polyethylene terephthalate. The release sheet 150 may include an undercoat layer (not illustrated) between the release layer 160 and the base material 170.

### Other Layer

The above-described sheet may have a layer other than the base material and the pressure sensitive adhesion layer. For example, an additional pressure sensitive adhesion layer may be provided on a surface of the base material on the opposite side of the pressure sensitive adhesion layer. The sheet can be attached to another object via such pressure sensitive adhesion layer. The type of the additional pressure sensitive adhesion layer is not particularly limited, and for example, the additional pressure sensitive adhesion layer can be formed using a general pressure sensitive adhesive.

### Manufacturing Method for Pressure Sensitive Adhesion Layer and Sheet

The method for manufacturing the pressure sensitive adhesion layer and the sheet is not particularly limited. For example, the sheet in which the pressure sensitive adhesion layer 110 is provided on the base material 120 can be manufactured as follows. First, an organic solvent is added to a raw material composition containing each of the components of the pressure sensitive adhesion layer 110 described above to prepare a solution of the raw material composition. Then, a pressure sensitive adhesion layer can be provided on the base material 120 after forming a coating film by applying the solution onto the base material 120 and then drying the coating film. Further, treatment for providing unevenness on the surface of the pressure sensitive adhesion layer is performed, whereby the pressure sensitive adhesion layer 110 having unevenness can be formed.

Examples of the organic solvent used for preparing the solution of the raw material composition include toluene, ethyl acetate, and methyl ethyl ketone. Examples of the solution coating method include spin coating, spray coating, bar coating, knife coating, roll coating, roll knife coating, blade coating, die coating, gravure coating, and printing (e.g., screen printing and ink-jet printing).

There is also no particular limitation on the treatment for providing unevenness on the surface of the pressure sensitive adhesion layer 110. For example, unevenness can be provided on the surface of the pressure sensitive adhesion layer 110 using an imprint method. In the imprint method, it is possible to use a mold whose surface has a shape complementary to the unevenness to be provided. Specifically, unevenness can be provided on the surface of the pressure sensitive adhesion layer by heating the pressure sensitive adhesion layer provided on the base material while pressing the pressure sensitive adhesion layer with a mold. As a more specific method, the following can be given: the pressure sensitive adhesion layer is pressed with a mold, the pressure sensitive adhesion layer is heated and maintained for a predetermined time, and thereafter the pressure sensitive adhesion layer is cooled and then the mold can be removed. When the pressure sensitive adhesion layer is heated, for example, the pressure sensitive adhesion layer can be heated to a temperature higher than the softening point of the pressure sensitive adhesion layer. The time for which the pressure sensitive adhesion layer is maintained in a heated state is also not particularly limited. For example, the pressure sensitive adhesion layer may be maintained for 10 seconds or more, or may be maintained for 10 minutes or less. As a specific method for heating the pressure sensitive adhesion layer while pressing the pressure sensitive adhesion layer with the mold, there is a method for vacuum-laminating the pressure sensitive adhesion layer provided on the base material and the mold. Instead of carrying out two steps of forming a pressure sensitive adhesion layer and forming unevenness, a pressure sensitive adhesion layer having unevenness on the surface thereof may be formed on the base material in one step. As the mold, the release sheet 150 including the release layer 160 having unevenness as described above may be used.

As another method, the pressure sensitive adhesion layer 110 having a rough surface can be provided by spray-coating with a solution of the raw material composition. In addition, the pressure sensitive adhesion layer 110 having a rough surface or a fibrous surface can be provided by adding a filler to a solution of the raw material composition and applying such a solution. As still another method, the pressure sensitive adhesion layer 110 having the shape of unevenness can be directly provided on the base material 120 by applying a solution of the raw material composition in accordance with a desired pattern using a printing method such as an ink-jet method.

### Method for Using Pressure Sensitive Adhesive Sheet

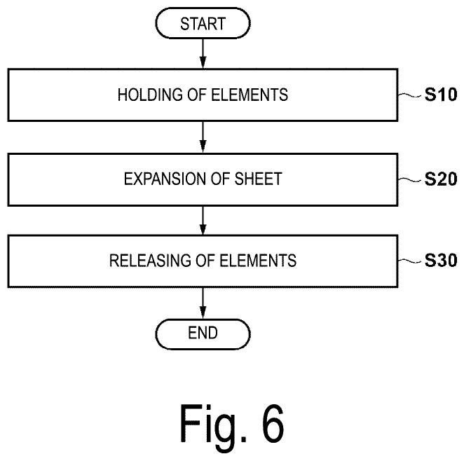

The sheet according to the present embodiment can be used for fixing, holding, or transferring an object. The type of the object is not particularly limited, and may be, for example, an element described later. For example, the sheet according to one embodiment is a sheet for element fixation, which can be used for fixing an element to the pressure sensitive adhesion layer. Further, the sheet according to one embodiment is an element transfer sheet, which can be used for temporarily holding an element on the pressure sensitive adhesion layer and transferring the held element to a desired position. As a specific example, the sheet according to the present embodiment can be used for transferring a semiconductor chip obtained by dicing to a desired position. An element release method and an element transfer method using the sheet according to the present embodiment will be described with reference to a flowchart in FIG. 6.

### S10: Holding of Elements

In S10, elements are held on the pressure sensitive adhesion layer of the pressure sensitive adhesive sheet according to the present embodiment. The type of element is not particularly limited. Examples of the element may include a semiconductor chip such as an LED chip, a semiconductor chip with a protective film, and a semiconductor chip with a die attach film (DAF). Further, examples of the element may also include a micro light emitting diode, a mini light emitting diode, a power device, micro electro mechanical systems (MEMS), a controller chip, and constituent elements thereof. The element may be an individual product such as a wafer, a panel, or a substrate. The element may have a circuit surface on which there is formed an integrated circuit including circuit elements such as transistors, resistors, and capacitors. The element is not necessarily limited to an individual product, and may be any of various wafers or various substrates that are not individualized.

In addition, the size of the element is not particularly limited. The size of the element may be, for example, preferably 100 μm² or more, more preferably 500 μm² or more, and even more preferably 1000 μm² or more. On the other hand, the size of the element may be preferably 100 mm² or less, more preferably 25 mm² or less, and even more preferably 1 mm² or less.

Examples of the wafer include semiconductor wafers such as a silicon wafer, a silicon carbide (SiC) wafer, and a compound semiconductor wafer (e.g., a gallium phosphide (GaP) wafer, a gallium arsenide (GaAs) wafer, an indium phosphide (InP) wafer, and a gallium nitride (GaN) wafer). The size of the wafer is not particularly limited, but is preferably 6 inches (approximately 150 mm in diameter) or larger, and more preferably 12 inches (approximately 300 mm in diameter) or larger. The shape of the wafer is not limited to a circle, and may be, for example, a quadrangle shape such as a square or a rectangle.

Examples of the panel include a fan-out type semiconductor package (e.g., FOWLP or FOPLP). That is, the object to be treated may be a semiconductor package before or after individualization in a fan-out type semiconductor package manufacturing technique. The size of the panel is not particularly limited, but may be, for example, a quadrangle substrate of approximately 300 to 700 mm.

Examples of the substrate include a glass substrate, a sapphire substrate, and a compound semiconductor substrate.

In one embodiment, elements are transferred from a holding substrate to a pressure sensitive adhesive sheet, and the pressure sensitive adhesive sheet holds the transferred elements. For example, a semiconductor wafer can be attached onto a wafer substrate, and the semiconductor wafer can be diced. Then, the elements on the wafer substrate obtained by dicing can be brought into close contact with the pressure sensitive adhesion layer 110 of the pressure sensitive adhesive sheet. Thereafter, by applying an external stimulus such as a laser beam, the adhesion between the wafer substrate and the elements can be lowered. By such a manufacturing process, the elements can be transferred from the wafer substrate to the semiconductor transfer sheet. As another method, elements obtained by dicing a semiconductor wafer are transferred to a holding substrate, whereby the holding substrate to which the elements are attached can be obtained. Then, the elements attached to the holding substrate can be transferred to the pressure sensitive adhesion layer 110 of the pressure sensitive adhesive sheet by a similar method.

In another embodiment, elements attached to a holding substrate may be separated from the holding substrate by an external stimulus. Specifically, the elements are relatively separated from the holding substrate. Further, the elements relatively come close to a pressure sensitive adhesive sheet. Then, when the elements come into contact with the pressure sensitive adhesion layer 110 of the sheet, the elements are separated from the holding substrate and caught by the sheet. The type of external stimulus is not particularly limited, and examples thereof include energy application, cooling, expansion of the holding substrate, and physical stimulus (e.g., pressing the back face of the holding substrate with a pin or the like). By using one or more of these external stimuli, the bonding force between the holding substrate and the element can be reduced and the element can be separated from the holding substrate. For example, the element can be separated from the holding substrate by irradiation with a laser beam (laser lift-off method). In such an embodiment, when the separated elements approach the pressure sensitive adhesion layer 110, pressure is generated between the elements and the pressure sensitive adhesion layer 110. However, since the surface of the pressure sensitive adhesion layer 110 has unevenness, the pressure generated between the elements and the pressure sensitive adhesion layer 110 is alleviated, thereby making it easier to catch the elements at desired positions of the sheet.

In an additional embodiment, a plurality of elements can be formed by dicing elements held on the pressure sensitive adhesion layer 110 of the pressure sensitive adhesive sheet. For example, a semiconductor wafer is attached to the pressure sensitive adhesion layer 110. Then, the plurality of elements are formed by dicing the semiconductor wafer on the pressure sensitive adhesion layer 110. With such a method as well, the pressure sensitive adhesive sheet can hold the elements. Such a dicing process can be carried out before a pressure sensitive adhesive sheet expanding step (S20) described below.

### S20: Expansion of Pressure Sensitive Adhesive Sheet

Thereafter, the elements held on the pressure sensitive adhesion layer 110 of the pressure sensitive adhesive sheet are released. By using the pressure sensitive adhesive sheet according to the present embodiment, the elements can be released from the pressure sensitive adhesion layer 110 with a small pickup force. On the other hand, in order to release the elements from the pressure sensitive adhesion layer 110 with a smaller pickup force, the pressure sensitive adhesive sheet holding the elements on the pressure sensitive adhesion layer 110 can be expanded in the plane direction in S20. Since the holding power for the elements is reduced by expanding the sheet, the elements can be easily released in the subsequent step.

A method for expanding the sheet is not particularly limited. For example, the sheet may be expanded in one direction, in two directions, or in other multiple directions.

The expansion rate of the pressure sensitive adhesive sheet is also not particularly limited. For example, from the viewpoint of sufficiently reducing the holding power for the object, the expansion rate of the pressure sensitive adhesive sheet in one direction may be 1% or more, or 5% or more. From the viewpoint of preventing breakage of the pressure sensitive adhesive sheet, the expansion rate of the pressure sensitive adhesive sheet in one direction may be 50% or less, or 20% or less. From a similar viewpoint, the expansion rate of the pressure sensitive adhesive sheet in two directions orthogonal to each other may be 1% or more, or 5% or more; on the other hand, it may be 50% or less, or 20% or less.

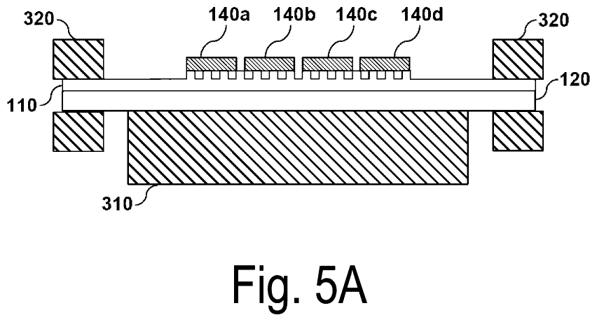

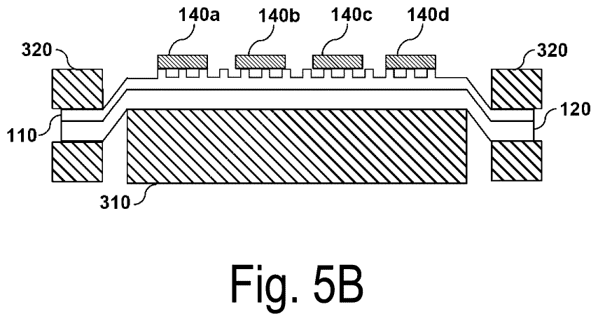

As a specific example, the sheet is fixed to a frame and a pedestal is pressed against the sheet in the frame, thereby making it possible to expand the sheet. Such an example will be described below with reference to FIGS. 5A and 5B. FIG. 5A illustrates a state in which the sheet holds elements 140a to 140d. As illustrated in FIG. 5A, the outer peripheral portion of the sheet can be fixed to a frame 320. The shape of the frame 320 is not particularly limited. For example, the frame 320 may be a circular or rectangular frame-like member having an opening. In one embodiment, a circular ring frame is used as the frame. By using the ring frame, the sheet can be expanded in all directions.

Then, the sheet fixed to the frame 320 is brought into contact with a pedestal 310, and the frame 320 is displaced (pulled down) toward the pedestal 310 side as illustrated in FIG. 5B, whereby the sheet can be expanded. The configuration of the pedestal 310 is not particularly limited, and may have, for example, a cylindrical shape or a rectangular parallelepiped shape. The pedestal 310 may have a mesh shape or a ring shape. The frame 320 may be displaced toward the pedestal 310, for example, at a speed of 0.1 mm/sec or more, or at a speed of 1 mm/sec or more. In this case, the displacement amount of the frame 320, that is, the pulled-down amount thereof may be, for example, equal to or greater than 1 mm or equal to or greater than 5 mm, from the viewpoint of sufficiently lowering the holding power for the object. On the other hand, from the viewpoint of suppressing the breakage of the pressure sensitive adhesive sheet, the displacement amount of the frame 320 may be equal to or less than 30 mm or may be equal to or less than 20 mm.

### S30: Releasing of Elements

In S30, the elements are released from the pressure sensitive adhesion layer 110 of the pressure sensitive adhesive sheet. In the present embodiment, the elements are released from the pressure sensitive adhesion layer 110 of the pressure sensitive adhesive sheet expanded in the plane direction. The method for releasing the elements is not particularly limited. For example, the above-described method can be used as a method for transferring the elements attached to the holding substrate to the pressure sensitive adhesive sheet. Specifically, the elements can be moved to the transfer destination by bringing the substrate or sheet of the transfer destination close to the surfaces of the elements and pressing the surface of the sheet on the opposite side of the elements by using a pin or the like. As another method, specifically, the elements can be each released from the pressure sensitive adhesion layer 110 of the sheet by using a suction member such as a vacuum chuck so as to be moved to the desired position of the transfer destination. When the holding power by the pressure sensitive adhesion layer 110 is reduced due to the expansion of the sheet, the elements may be released from the pressure sensitive adhesion layer 110 of the sheet without applying a physical stimulus from the opposite surface of the pressure sensitive adhesion layer 110 of the sheet. Furthermore, the adhesion between the pressure sensitive adhesive sheet and the elements may be reduced by bringing the elements held on the pressure sensitive adhesive sheet into close contact with the substrate or sheet of the transfer destination and further applying an external stimulus such as a laser beam. With such a method as well, the elements can be moved from the pressure sensitive adhesive sheet to the transfer destination. In this case, due to the expansion of the pressure sensitive adhesive sheet, the relative arrangement of the plurality of elements at the transfer destination changes from the relative arrangement of the plurality of elements before the sheet expansion.

Through such a procedure, the element can be transferred to an optional transfer destination by using the pressure sensitive adhesive sheet. An electronic component or a semiconductor device including an element can be manufactured by using such a transfer method. The elements held on the pressure sensitive adhesive sheet may be subjected to treatment or processing.

### EXAMPLES

The present invention will be described in further detail below through the presentation of examples. However, the present invention is in no way limited to the examples described below. Note that “parts” and “%” in each example are based on the mass of the solids content unless otherwise specified.

In examples and comparative examples, the following compounds were used.

### Component (A): Acrylic Resin

As the acrylic resin, an acryl-based copolymer (monomer mass ratio: 2-ethylhexyl acrylate/2-hydroxyethyl acrylate/acrylic acid=92.8/7.0/0.2, mass-average molecular weight (Mw): 1100 thousand) was used.

### Component (B): Energy-Reactive Resin

As an energy-reactive resin, tricyclodecane dimethanol diacrylate was used.

### Component (C): Cross-Linker

As a cross-linker, isocyanurate type polyisocyanate derived from hexamethylene diisocyanate was used.

### Component (D): Photopolymerization Initiator

As a photopolymerization initiator, 2,4,6-trimethylbenzoyl diphenylphosphine oxide was used.

### Thickness Measurement

The thicknesses of the layers and portions were measured at 23° C. using a constant pressure thickness gauge manufactured by Teclock Corporation (model number: “PG-02J”, in accordance with standard specifications: JIS K6783, Z1702, and Z1709).

### Pickup Force Evaluation

The pickup force of the sheet obtained in each example was evaluated as follows. First, a pressure sensitive adhesion layer of the sheet obtained in each example was attached to a ring frame (made of stainless steel, 194 mm in inside diameter), and the sheet was cut corresponding to the outside diameter of the ring frame.

Subsequently, a wafer substrate (mirror silicon wafer, 6 inches, 150 μm in thickness) was fixed to a separately prepared dicing tape. Then, the wafer substrate was diced into a square of 10 mm×10 mm to obtain a plurality of elements (silicon chips, each having a size of 10 mm×10 mm×150 μm). The obtained plurality of elements were attached to the pressure sensitive adhesion layer of the sheet at the center portion inside the ring frame in such a manner that the mirror face was attached to the pressure sensitive adhesion layer. The attachment was made by laminating at room temperature (23° C.). Then, the dicing tape was released to transfer the plurality of elements from the dicing tape to the sheet. Thus, the sheet on which the plurality of elements were mounted and which was supported by the ring frame was obtained as a sample for evaluation. Crook-shaped hooks were fixed to the plurality of elements of the obtained evaluation sample by using an adhesive.

The evaluation sample in which the crook-shaped hooks were fixed to the elements was set in an expanding device illustrated in FIG. 5A. In a state where the elements were supported by the pedestal 310 across the sheet, the frame 320 as a ring frame was pushed down under the condition of a speed being 1 mm/sec. The pushed-down distance (pulled-down amount) was 0 mm, 5 mm, or 10 mm. Thereafter, a measurement terminal of a push-pull gauge (manufactured by Aikoh Engineering Co., Ltd., product name: “RX-5”) was coupled to the crook-shaped hook, and a pickup force required for picking up the element from the pressure sensitive adhesive sheet was measured using the push-pull gauge.

### Example 1

A pressure sensitive adhesive composition was prepared by dissolving 100 parts by mass of the solids content of the acrylic resin (A), 25 parts by mass of the solids content of the energy-reactive resin (B), 1.25 parts by mass of the solids content of the cross-linker (C), and 0.75 parts by mass of the solids content of the photopolymerization initiator (D) in toluene. This pressure sensitive adhesive composition was applied onto a release treatment face of a release sheet (manufactured by LINTEC Corporation, trade name: SP-PET382150, a product in which a silicone-based release agent is laminated on a polyethylene terephthalate film, 38 μm in thickness), and the obtained coating was dried at 100° C. for two minutes, whereby a pressure sensitive adhesion layer having a thickness of 25 μm was formed. The shear storage modulus of the obtained pressure sensitive adhesion layer was 2.04 MPa.

On this pressure sensitive adhesion layer, an EMAA film (an ethylene-methacrylic acid copolymer film, acid content being 9 mass %, one surface thereof being satin-finished by embossing treatment, 80 μm in thickness) was used as the base material, where a non-embossed surface of the EMAA film was pasted onto the pressure sensitive adhesion layer.

After the release sheet was released, the pressure sensitive adhesion layer was pasted on a replica mold formed with unevenness in advance, and then vacuum lamination was carried out at 60° C. for 300 seconds. Subsequently, the sheet was irradiated with ultraviolet rays at illuminance of 200 mW/cm² and a light amount of 800 mJ/cm² by using an ultraviolet ray irradiator (manufactured by Heraeus K. K.) to prepare a sheet having a shape of unevenness on the surface thereof. The shape of unevenness formed on the pressure sensitive adhesion layer of the sheet was a shape in which pillars were arranged in a lattice pattern as depicted in FIG. 2A. The pitch P between the pillars in the sheet was 20 μm. The tip diameter (T) of each pillar illustrated in FIG. 4A was 8 μm, and the base-portion diameter (D) was 16 μm. The ratio of an area of the adhesion portion (that is, an area of the tip face of the convex portion) of the caught element by the pressure sensitive adhesion layer to an area of the sheet was about 12.6%. The height (H) of each pillar (convex portion) and the thickness(S) of the underlying base illustrated FIG. 4A were as depicted in Table 1. As the replica mold, a mold having a surface shape complementary to the shape of unevenness discussed above was used.

The sheet thus obtained was subjected to the evaluation of the pickup force as described above. The measured pickup forces are depicted in Table 1.

### Examples 2 to 5

A sheet was prepared and evaluated in the same manner as in Example 1 except that the pressure sensitive adhesion layer was formed to have the height (H) of the pillar (convex portion) and the thickness(S) of the underlying base respectively depicted in Table 1.

### Comparative Examples 1 to 3

A sheet was prepared and evaluated in the same manner as in Example 1 except that the pressure sensitive adhesion layer was formed to have the height (H) of the pillar (convex portion) and the thickness(S) of the underlying base respectively depicted in Table 1. In Comparative Example 1, the pressure sensitive adhesion layer had a flat surface and did not have any convex portion.

TABLE 1

| | Height | Thick- | | | | |
|---|---|---|---|---|---|---|
| | (H) | ness (S) | | Pickup force [N/100 mm²] | | |
| | [μm] of | [μm] of | | No | 5 mm | 10 mm |
| | convex | underlying | | pulling- | pulling- | pulling- |
| | portion | base | S/H | down | down | down |
| Example 1 | 8 | 17 | 2.13 | 8.18 | 5.88 | 2.58 |
| Example 2 | 4 | 6 | 1.50 | 7.46 | 5.74 | 1.39 |
| Example 3 | 4 | 11 | 2.75 | 8.45 | 7.03 | 2.39 |
| Example 4 | 4 | 16 | 4.00 | 8.23 | 7.10 | 2.07 |
| Example 5 | 6 | 11 | 1.83 | 7.67 | 6.38 | 2.17 |
| Comparative | 0 | 20 | — | 9.49 | 9.14 | 9.24 |
| Example 1 | | | | | | |
| Comparative | 4 | 21 | 5.25 | 9.02 | 8.33 | 3.53 |
| Example 2 | | | | | | |
| Comparative | 2 | 11 | 5.50 | 10.31 | 8.58 | 2.92 |
| Example 3 | | | | | | |

As can be seen from the comparison between Examples 1 to 5 and Comparative Example 1, by providing unevenness on the surface of the pressure sensitive adhesion portion, an effect of reducing the pickup force when the sheet was expanded was obtained. Further, as can be seen from the comparison between Examples 1 to 5 and Comparative Examples 2 and 3, when the ratio represented by the expression of (thickness(S) of underlying base/height (H) of convex portion) was less than 4.75, the effect of reducing the pickup force was obtained; in particular, when the sheet was expanded, the pickup force was able to be further reduced. In particular, as can be seen from the comparison between Example 2, Example 3, and Comparative Example 3, it was confirmed that the pickup force generally tends to be further reduced by further reducing the ratio represented by the expression of (thickness(S) of underlying base/height (H) of convex portion).

The invention is not limited to the above-described embodiments, and various modifications and changes can be made within the scope of the gist of the invention.

What is claimed is:

1. A pressure sensitive adhesive sheet, comprising a base material and a pressure sensitive adhesion layer having enevenness on a surface, the pressure sensitive adhesive sheet being characterized in that:
the pressure sensitive adhesion layer comprises: an underlying base constituted by a part from a concave portion where, in a thickness direction of the pressure sensitive adhesion layer, a thickness of the pressure sensitive adhesion layer is smallest, to a face on an opposite side of the surface with the unevenness; and a convex portion provided on the underlying base, and
the pressure sensitive adhesion layer satisfies Relational Expression (1) given below:
$$0.25 < S / H < 4.75 \qquad Relational Expression ( 1 )$$
where in Relational Expression (1), S represents a thickness of the underlying base, and H represents a height of the convex portion.

2. The pressure sensitive adhesive sheet according to claim 1, characterized in that the underlying base has a uniform thickness.

3. The pressure sensitive adhesive sheet according to claim 1, characterized in that the pressure sensitive adhesion layer includes a plurality of convex portions, and a height of the plurality of convex portions is uniform.

4. The pressure sensitive adhesive sheet according to claim 1, characterized in that the height of the convex portion is 1 μm or more and 15 μm or less.

5. The pressure sensitive adhesive sheet according to claim 1, characterized in that the thickness of the underlying base is 1 μm or more and 50 μm or less.

6. The pressure sensitive adhesive sheet according to claim 1, characterized in that the underlying base and the convex portion are integrated with each other.

7. The pressure sensitive adhesive sheet according to claim 1, characterized in that the pressure sensitive adhesion layer includes a plurality of convex portions separated from each other with a boundary defined by the concave portion, and a pitch of the plurality of convex portions is 1 μm or more and 100 μm or less.

8. The pressure sensitive adhesive sheet according to claim 1, characterized in that a shear storage modulus of the pressure sensitive adhesion layer is 0.001 MPa or more and 100 MPa or less.

9. The pressure sensitive adhesive sheet according to claim 1, characterized in that a Young's modulus of the base material is 2500 MPa or less.

10. The pressure sensitive adhesive sheet according to claim 1, characterized by being a sheet for element fixation.

11. The pressure sensitive adhesive sheet according to claim 1, characterized by being an element transfer sheet.

12. The pressure sensitive adhesive sheet according to claim 1, characterized in that the pressure sensitive adhesive sheet is expandable in a plane direction, and holding power for an object on the pressure sensitive adhesive sheet after expansion is reduced as compared with the holding power before expansion.

13. A method for releasing an element from a pressure sensitive adhesive sheet, the method comprising:
expanding, in a plane direction, the pressure sensitive adhesive sheet according to claim 1 holding an element on a pressure sensitive adhesion layer; and
releasing the element from the pressure sensitive adhesion layer of the pressure sensitive adhesive sheet expanded in the plane direction.

14. The method for releasing according to claim 13, the method further comprising forming a plurality of elements by dicing the elements held on the pressure sensitive adhesion layer before the step of expanding the pressure sensitive adhesive sheet.
